(19) United States
(12) Patent Application Publication
(10) Pub. No.: US 2002/0096729 A1
(43) Pub. Date: Jul. 25, 2002

(54) Stacked package structure of image sensor

(76) Inventors: Hsiu Wen Tu, Hsinchu Hsien (TW); Wen Chuan Chen, Hsinchu Hsien (TW); Mon Nan Ho, Hsinchu Hsien (TW); Li Huan Chen, Hsinchu Hsien (TW); Nai Hua Yeh, Hsinchu Hsien (TW); Yen Cheng Huang, Hsinchu Hsien (TW); Yung Sheng Chiu, Hsinchu Hsien (TW); Wen Tsan Lee, Hsinchu Hsien (TW); Joe Liu, Hsinchu Hsien (TW); Wu Hsiang Lee, Hsinchu Hsien (TW); Meng Ru Tsai, Hsinchu Hsien (TW)

Correspondence Address: Keith Kline, PRO-TECHTOR INTERNATIONAL SERVICES, 20775 Norada Court, Saratoga, CA, 95070-3018, US

(21) Appl. No.: 09/770,048

(22) Filed: Jan. 24, 2001

(51) Int. Cl. H01L 21/00

(52) U.S. Cl. 257/433; 438/64

(57) ABSTRACT

A stacked package structure of an image sensor for electrically connecting to a printed circuit board includes a substrate, an integrated circuit, an image sensing chip, and a transparent layer. The substrate has a first surface and a second surface opposite to the first surface. The first surface is formed with signal input terminals. The second surface is formed with signal output terminals for electrically connecting the substrate to the printed circuit board. The integrated circuit is mounted on the first surface of the substrate and electrically connected to the signal input terminals of the substrate. The image sensing chip is located above the integrated circuit to form a stacked structure with the integrated circuit for electrically connecting to the signal input terminals of the substrate. The transparent layer covers the image sensing chip. The image sensing chip receives image signals via the transparent layer and converts the image signals into electrical signals that are to be transmitted to the substrate. Thus, the image sensing chip of the image sensing product and the integrated circuit can be integrally packaged.

### BACKGROUND OF THE INVENTION

1. Field of the Invention

The invention relates to a stacked structure of an image sensor, in particular, to a structure in which integrated circuits and image sensing chips, both having different functions, are packaged into a package body so as to reduce the number of package substrates and to integrally package the integrated circuits and image sensing chips both having different functions.

2. Description of the Related Art

A general sensor is used for sensing signals, which may be optical or audio signals. The sensor of the invention is used for receiving image signals and transforming the image signals into electrical signals that are transmitted to a printed circuit board.

A general image sensor is used for receiving image signals and converting the image signals into electrical signals that are transmitted to a printed circuit board. The image sensor is then electrically connected to other integrated circuits to have any required functions. For example, the image sensor may be electrically connected to a digital signal processor that processes the signals generated from the image sensor. Further, the image sensor may also be electrically connected to a micro controller, a central processor, or the like, so as to have any required functions.

However, since the conventional image sensor is packaged, the integrated circuits corresponding to the image sensor have to be individually packaged with the image sensor. Then, the packaged image sensor and various signal processing units are electrically connected onto the printed circuit board. Thereafter, the image sensor is electrically connected to the signal processing units by a plurality of wirings, respectively. Therefore, in order to individually package each of the signal processing units and the image sensor, a plurality of substrate and package bodies have to be used, thereby increasing the manufacturing costs. Furthermore, the required area of the printed circuit board should be larger when mounting each of the signal processing units onto the printed circuit board, so the products cannot be made small, thin, and slight.

In order to solve the above-mentioned problems, the invention provides a stacked structure of an image sensor to overcome the disadvantages caused by the conventional image sensor.

### SUMMARY OF THE INVENTION

It is therefore an object of the invention to provide a stacked package structure of an image sensor for reducing the number of packaged elements and lowering the package costs.

It is therefore another object of the invention to provide a stacked package structure of an image sensor for simplifying and facilitating the manufacturing processes.

It is therefore still another object of the invention to provide a stacked package structure of an image sensor for reducing the area of the image sensing products.

It is therefore yet another object of the invention to provide a packaged package structure of an image sensor for lowering the package costs and testing costs of the image sensing products.

According to one aspect of the invention, a stacked structure of an image sensor for electrically connecting to a printed circuit board includes a substrate, an integrated circuit, an image sensing chip, and a transparent layer. The substrate has a first surface and a second surface opposite to the first surface. The first surface is formed with signal input terminals. The second surface is formed with signal output terminals for electrically connecting the substrate to the printed circuit board. The integrated circuit is mounted on the first surface of the substrate and electrically connected to the signal input terminals of the substrate. The image sensing chip is located above the integrated circuit to form a stacked structure with the integrated circuit and is used for electrically connecting to the signal input terminals of the substrate. The transparent layer covers the image sensing chip. The image sensing chip receives image signals via the transparent layer and converts the image signals into electrical signals that are to be transmitted to the substrate.

Thus, the image sensing chip of the image sensing product and the integrated circuit can be integrally packaged.

### BRIEF DESCRIPTION OF THE DRAWINGS

FIG. 1 shows a stacked package structure of an image sensor in accordance with a first embodiment of the invention.

FIG. 2 shows a stacked package structure of an image sensor in accordance with a second embodiment of the invention.

FIG. 3 shows a stacked package structure of an image sensor in accordance with a third embodiment of the invention.

FIG. 4 shows a stacked package structure of an image sensor in accordance with a fourth embodiment of the invention.

### DETAIL DESCRIPTION OF THE INVENTION

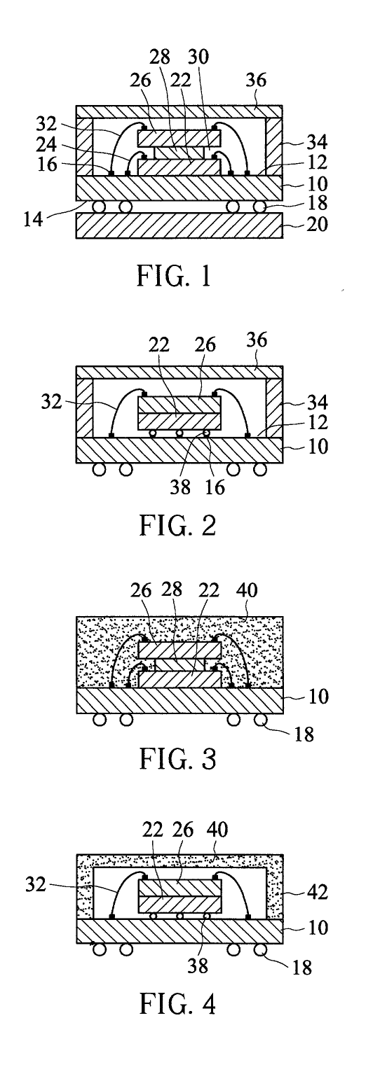

Referring to FIG. 1, the stacked package structure of the image sensor includes a substrate 10, an integrated circuit 22, an image sensing chip 26, a projection layer 34, and a transparent layer 36.

The substrate 10 has a first surface 12 and a second surface 14 opposite to the first surface 12. The first surface 12 is formed with signal input terminals 16. The second surface 14 is formed with signal output terminals 18, which may be metallic balls arranged in the form of a ball grid array, for electrically connecting to a printed circuit board 20. Thus, the signals form the substrate 10 can be transmitted to the printed circuit board 20.

The integrated circuit 22 may be a signal processing unit such as a digital signal processor, a micro processor, a central processing unit (CPU), or the like. The integrated circuit 22 is arranged on the first surface 12 of the substrate 10 and is electrically connected to the signal input terminals 16 of the substrate 10 by way of wire bonding. Thus, the integrated circuit 22 can be electrically connected to the substrate 10 for transmitting the signals from the integrated circuit 22 to the substrate 10.

The image sensing chip 26 is arranged above the integrated circuit 22 to form a stacked structure with the integrated circuit 22. In order to prevent the metal wirings 24 located above the integrated circuit 22 from being pressed by the image sensing chip 26, a spacer 28 is provided between the integrated circuit 22 and the image sensing chip 26 to form a gap 30 therebetween. Thus, parts of the metal wirings 24 are located within the gap 30. The image sensing chip 26 is electrically connected to the signal input terminals 16 of the substrate 10 by the metal wirings 32. Thus, the image sensing chip 26 is electrically connected to the substrate 10 so that the signals form the image sensing chip 26 can be transmitted to the substrate 10. If the integrated circuit 22 is a digital signal processor, the signals from the image sensing chip 26 can be processed in advance and then transmitted to the printed circuit board 20.

The projection layer 34 is a frame structure located on the first surface 12 of the substrate 10 for surrounding the integrated circuit 22 and the image sensing chip 26.

The transparent layer 36 may be a transparent glass covering the projection layer 34 for sealing the image sensing chip 26 and the integrated circuit 22. The image sensing chip 26 can receive image signals via the transparent layer 36 and convert the image signals into electrical signals that are to be transmitted to the substrate 10.

Referring to FIG. 2, the integrated circuit 22 is formed with electroconductive metals 38 electrically connecting to the signal input terminals 16 of the substrate 10 by way of flip chip bonding. Thus, the integrated circuit 22 is electrically connected to the substrate 10. The image sensing chip 26 is electrically connected to the signal input terminals 16 of the substrate 10 via the metal wirings 32 by way of wire bonding

Referring to FIG. 3, the transparent layer is a transparent glue 40. After the image sensing chip 26 is stacked above the integrated circuit 22 and the image sensing chip 26 and the integrated circuit 22 are electrically connected to the substrate 10, a transparent glue 40 is provided for covering the image sensing chip 26 and the integrated circuit 22. Thus, the image sensing chip 26 also can receive image signals via the transparent glue 40 and convert the image signals into electrical signals that are to be transmitted to the substrate 10. The electrical signals are then processed by the integrated circuit 22.

Referring to FIG. 4, the transparent layer is a “ [symbol] -shaped” transparent glue 40 having a supporting column 42 arranged on the first surface 12 of the substrate 10. The “ [symbol] -shaped” transparent glue 40 can be formed by injection molding or press molding. After the integrated circuit 22 is electrically connected to the substrate 10 by way of flip chip bonding, the image sensing chip 26 is stacked above the integrated circuit 22. Then, the image sensing chip 26 is electrically connected to the substrate 10 via the metal wirings 32 by way of wire bonding. Thereafter, the “ [symbol] -shaped” transparent glue 40 is directly mounted on the first surface 12 of the first surface 12 for sealing the image sensing chip 26 and the integrated circuit 22. Thus, the image sensing chip 26 can receive image signals via the “ [symbol] -shaped” transparent glue 40 and convert the image signals into electrical signals that are to be transmitted to the substrate.

According to the above-mentioned structure, the invention has the following advantages.

1. Since the image sensing chip 26 and the integrated circuit 22 can be integrally packaged, the material forming the substrate 10 can be reduced, thereby lowering the manufacturing costs of the image sensing products.

2. Since the image sensing chip 26 and the integrated circuit 22 can be integrally packaged, the area of the image sensing products can be reduced.

3. Since the image sensing chip 26 and the integrated circuit 22 can be integrally packaged, there is only one package body. Thus, only one testing fixture needs be used, and the testing costs can also be reduced.

4. Since the image sensing chip 26 and the integrated circuit 22 can be integrally packaged, two chips can be packaged by only one packaging process. The package costs can thus be effectively lowered.

While the invention has been described by way of example and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. A stacked package structure of an image sensor for electrically connecting to a printed circuit board, comprising:
a substrate having a first surface and a second surface opposite to the first surface, the first surface being formed with signal input terminals, the second surface being formed with signal output terminals for electrically connecting the substrate to the printed circuit board;
an integrated circuit mounted on the first surface of the substrate and electrically connected to the signal input terminals of the substrate;
an image sensing chip located above the integrated circuit to form a stacked structure with the integrated circuit and electrically connected to the signal input terminals of the substrate; and
a transparent layer covering the image sensing chip, wherein the image sensing chip receives image signals via the transparent layer and converts the image signals into electrical signals that are to be transmitted to the substrate.

2. The stacked package structure of the image sensor according to claim 1, wherein the signal output terminals on the second surface of the substrate are metallic balls arranged in the form of a ball grid array for electrically connecting to the printed circuit board.

3. The stacked package structure of the image sensor according to claim 1, wherein the integrated circuit is a signal processing unit.

4. The stacked package structure of the image sensor according to claim 3, wherein the signal processing unit is a digital signal processor for processing the signals from the image sensing chip.

5. The stacked package structure of the image sensor according to claim 3, wherein the signal processing unit is a micro controller.

6. The stacked package structure of the image sensor according to claim 3, wherein the signal processing unit is a central processing unit (CPU).

7. The stacked package structure of the image sensor according to claim 1, wherein the integrated circuit is electrically connected to the signal input terminals of the substrate via a plurality of wirings.

8. The stacked package structure of the image sensor according to claim 1, wherein the integrated circuit is electrically connected to the signal input terminals of the substrate by way of flip chip bonding.

9. The stacked package structure of the image sensor according to claim 1, wherein the transparent layer is a transparent glass.

10. The stacked package structure of the image sensor according to claim 1, wherein a projection layer is arranged on the periphery of the first surface of the substrate, and the transparent layer is arranged on the projection layer.

11. The stacked package structure of the image sensor according to claim 1, wherein the image sensing chip is electrically connected to the signal input terminals of the substrate via a plurality of metal wirings.

12. The stacked package structure of the image sensor according to claim 1, wherein the transparent layer is a transparent glue.

13. The stacked package structure of the image sensor according to claim 1, wherein the transparent layer is a “ [symbol] -shaped” transparent glue having a supporting column mounted on the first surface of the substrate.
